(19) United States
(12) Patent Application Publication
(10) Pub. No.: US 2007/0052466 A1
(43) Pub. Date: Mar. 8, 2007

(54) Flip-flop with improved operating speed

(76) Inventors: Oak-ha Kim, Seongnam-si (KR); Ji-ho Cho, Suwon-si (KR)

Correspondence Address: VOLENTINE FRANCOS, & WHITT PLLC, ONE FREEDOM SQUARE, 11951 FREEDOM DRIVE SUITE 1260, RESTON, VA, 20190, US

(21) Appl. No.: 11/513,156

(22) Filed: Aug. 31, 2006

(30) Foreign Application Priority Data
Sep. 2, 2005 (KR) 10-2005-0081843

(51) Int. Cl. H03K 3/00

(52) U.S. Cl. 327/218

(57) ABSTRACT

A flip-flop with an improved operating speed is disclosed. The flip-flop includes a switch unit, a latch unit and a reset controller. The switch unit transfers data to a first node in response to a clock signal. The latch unit latches the data apparent at the first node at a second node and outputs the data through an output node in response to the clock signal. The reset controller resets the output node in response to a reset control signal. The reset controller is connected between the second node and a first voltage and includes a transistor having a gate receiving the inverted form of the reset control signal.

### BACKGROUND OF THE INVENTION

1. Field of the Invention

Embodiments of the invention relate to a flip-flop circuit. More particularly, embodiments of the invention relate to a flip-flop having improved data transfer speed.

This application claims the benefit of Korean Patent Application No. 10-2005-0081843, filed on Sep. 2, 2005, the subject matter of which is hereby incorporated by reference.

2. Description of the Related Art

The so-called “D flip-flop” is a conventionally understood latch circuit. The D flip-flop essentially latches input data, and then outputs the latched data in response to a clock signal. Input data is typically latched on a rising (or a falling) edge of the clock signal and then output on the next rising edge (or falling edge) of the clock signal.

In its implementation, the D flip-flop may be viewed as consisting of two cascade-connected latch circuits. Data is commonly input to a first latch as the clock signal transitions to a high logic level (hereafter “high”), while data previously stored in the first latch is transferred to a second following latch when the clock signal transitions to a low logic level (hereafter “low”). The output state (i.e., the data state apparent at the second latch) does not vary when the clock signal is high or low, but data latched in the second latch is output when the clock signal transitions from low to high.

Figure (FIG.) 1 illustrates a conventional D flip-flop 100. Referring to FIG. 1, D flip-flop 100 includes dual 3-state buffers 112 and 131, inverters 110, 111, 151 and 152, and latches 120 and 140. Inverters 110 and 111 are serially connected and receive a clock signal CLK. Data apparent on data signal line D is transferred from 3-state buffer 112 to latch 120 in response to the output of inverters 110 and 111.

Latch 120 includes cross-coupled inverters 121 and 122, and latches an inverted data output through 3-state buffer 112 in response to clock signal CLK. The output of latch 120 is inverted by 3-state buffer 131 in response to the outputs of inverters 110 and 111. The data output from 3-state buffer 131 is output via inverter 151 as an output signal Q.

Latch 140 includes cross-coupled inverters 141 and 142, and latches the output from 3-state buffer 131 in response to clock signal CLK. The D flip-flop having this configuration outputs input data D as output signal Q when clock signal CLK transitions to high. However, the conventionally configured D flip-flop is characterized by a relatively long delay between data input and output, as input data D must pass through four elements (112, 121, 131 and 151) before being output as the output signal Q.

FIG. 2 illustrates another conventional D flip-flop 200. Referring to FIG. 2, D flip-flop 200 includes transfer gates TG1, TG2, TG3 and TG4 adapted to transfer data DI in response to a clock signal CLK. D flip-flop 200 also includes an inverter I1 inverting clock signal CLK, a first NAND gate 210 with an inverter I2 adapted to latch the output of transfer gate TG1 and make it apparent at a first node N1, and a second NAND gate 220 and an inverter I3 adapted to latch the output of transfer gate TG3 and make it apparent at a second node N2 as an output signal Q. First and second NAND gates 210 and 220 receive a reset control signal RST.

FIG. 3 is a circuit diagram of the respective first and second NAND gate of FIG. 2. When reset control signal RST is low, the output signal Q is reset to low by NAND gate 220 and inverter I3 irrespective of the logic level of the data DI. When reset control signal RST is high, D flip-flop 200 performs its latching operation in response to the logic level of clock signal CLK.

When clock signal CLK is low, transfer gates TG1 and TG4 are turned ON. Then, data DI passes through transfer gate TG1 and then is stored at first node N1 via NAND gate 210 and inverter I2.

When clock signal CLK transitions to high, transfer gates TG2 and TG3 are turned ON. Then, data DI apparent at first node N1 is stored at second node N2 via transfer gate TG3 as well as being made apparent at an output node NOUT through NAND gate 220 and inverter I3. Output signal Q is provided at output node NOUT.

As with D flip-flop 100 of FIG. 1, D flip-flop 200 is characterized by a relatively long delay between data input and output. For example, with reference to FIG. 3, NAND gate 220 is commonly constructed from two PMOS transistors TR1 and TR2 and two NMOS transistors TR3 and TR4 connected between a power supply voltage VDD and a ground voltage VSS. PMOS transistors TR1 and TR2 are connected in parallel between power supply voltage VDD and a node NC and NMOS transistors TR3 and TR4 are serially connected between the node NC and ground voltage VSS.

PMOS transistor TR2 and NMOS transistor TR3 operated in response to a first input signal IN1 while PMOS transistor TR1 and NMOS transistor TR4 operated in response to a second input signal IN2. Here, first and second input signals IN1 and IN2 are two input signals of NAND gate 220.

Data DI is transferred to output node NOUT through NAND gate 220 and inverter I3 on a rising edge of clock signal CLK. Since NAND gate 220 consists of the four transistors TR1, TR2, TR3 and TR4 it takes data DI a relatively long period of time to pass through NAND gate 220 and inverter I3. Accordingly, when D flip-flop 100 or 200 is incorporated within a high speed logic device, it's relatively long output delay may generate problems, and/or complicate the overall design or timing parameters.

### SUMMARY OF THE INVENTION

In one embodiment, the invention provides a flip-flop circuit comprising; a switch unit adapted to transfer data to a first node in response to a clock signal, a latch unit adapted to latch data apparent at the first node at a second node and then output the data through an output node in response to the clock signal, and a reset controller adapted to reset the output node in response to a reset control signal, the reset controller being connected between the second node and a first voltage and comprising a reset transistor having a gate adapted to receive an inverted reset control signal.

In another embodiment, the invention provides a flip-flop comprising; a switch unit adapted to transfer data to a first node in response to a first level of a clock signal and a second level of a reset control signal, a latch unit adapted to latch data apparent at the first node in response to a second level of the clock signal and the second level of the reset control signal, and a reset controller adapted to reset the output node in response to a first level of the reset control signal, wherein the data apparent at the second node is transferred via first and second serially connected inverters between the second node and the output node when the clock signal transitions to the second level.

In yet another embodiment, the invention provides a flip-flop circuit comprising; first transfer means transferring data in response to a clock signal and an inverted clock signal, first latch means storing the data output from the first transfer means at a first node in response to the clock signal and the inverted clock signal, second transfer means transferring the data output from the first latch means in response to the clock signal and the inverted clock signal, a second latch means storing the data output from the second transfer means at a second node and outputting it to an output node in response to the clock signal and the inverted clock signal, and a reset control means resetting the output node in response to a reset control signal, wherein data apparent at the first node is transferred via first and second inverters serially connected between the second node and the output node when the clock signal transitions to a second level.

### BRIEF DESCRIPTION OF THE DRAWINGS

FIG. 1 illustrates a conventional D flip-flop;

FIG. 2 illustrates another conventional D flip-flop;

FIG. 3 is a circuit diagram of the NAND gate of FIG. 2; and

FIG. 4 illustrates a flip-flop according to an embodiment of the present invention.

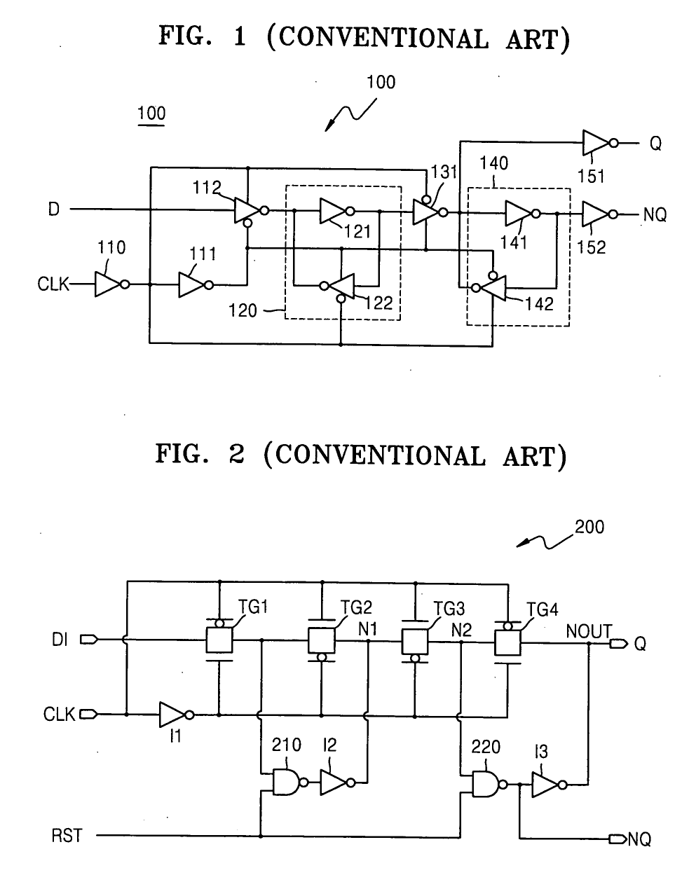

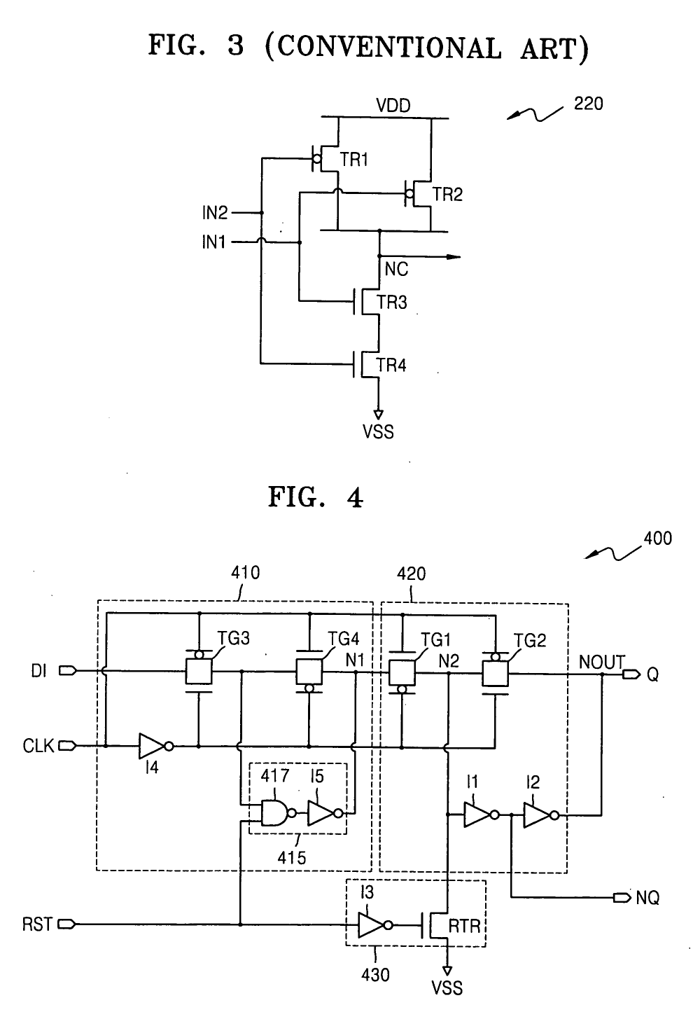

### DESCRIPTION OF EMBODIMENTS

The present invention will now be described more fully with reference to the accompanying drawings in the context of exemplary embodiments. The invention may, however, be embodied in many different forms and should not be construed as being limited to only the illustrated embodiments. Rather, the embodiments are presented as teaching examples of the invention.

FIG. 4 illustrates a flip-flop 400 according to an embodiment of the invention. Referring to FIG. 4, flip-flop 400 comprises a switch unit 410, a latch unit 420 and a reset controller 430. Switch unit 410 is adapted to transfer data to a first node N1 in response to a clock signal CLK.

In the illustrated embodiment, switch unit 410 transfers input data DI to first node N1 in response to a first level (high or low) of clock signal CLK and outputs the data apparent at first node N1 in response to a second level (low or high) of clock signal CLK. In the specific example illustrated, the first level of clock signal CLKJ corresponds to low and the second level corresponds to high, but those of ordinary skill in the art will recognize that these relative logic levels could be reversed in other embodiments of the invention.

Latch unit 420 latches data apparent at first node N1 and data apparent at a second node N2 in response to clock signal CLK, and then outputs the data via an output node NOUT. Specifically, latch unit 420 latches data at second node N2 in response to the first level of clock signal CLK and outputs the data apparent at second node N2 via the output node NOUT in response to the second level of clock signal CLK.

Reset controller 430 resets the output node NOUT in response to a reset control signal RST. Reset controller 430 is connected between second node N2 and a first voltage (e.g., ground voltage VSS) and comprises a reset transistor RTR having a gate receiving inverted reset control signal RST.

Of note, flip-flop 400 does not include NAND gate 220 conventionally required to implement the reset operation. Instead, reset transistor RTR is used to implement the reset operation, thereby improving data output speed for the circuit.

In flip-flop 400, data DI is stored at first node N1 when clock signal CLK is low and passes to second node N2 to be output through two inverters I1 and I2 on a rising edge of clock signal CLK. The output delay time for data DI may thus be reduced because an inverter has a much higher data transfer speed than a NAND gate.

The configuration and operation of flip-flop 400 illustrated of FIG. 4 will now be explained in some additional detail.

Latch unit 420 comprises a first transfer gate TG1 adapted to transfer data apparent at first node N1 to second node N2 in response to clock signal CLK. Latch unit 420 also comprises a second transfer gate TG2 switching (e.g., connecting and disconnecting) second node N2 to output node NOUT, and first and second inverters I1 and I2 serially connected between second node N2 and output node NOUT.

Reset controller 430 comprises a third inverter I3 inverting the reset control signal RST and reset transistor RTR connected between second node N2 and first voltage VSS. The gate of reset transistor RTR receives the output of third inverter I3. Here, reset transistor RTR may be an NMOS transistor and the first voltage VSS may be a ground voltage.

Switch unit 410 comprises a fourth inverter I4 inverting clock signal CLK, a third transfer gate TG3 transferring data DI in response to clock signal CLK and the output of fourth inverter I4, a fourth transfer gate TG4 switching third transfer gate TG3 to first node N1 in response to the output of fourth inverter I4, and an AND gate 415 adapted to logically AND the output of third transfer gate TG3 and reset control signal RST. The logically ANDed result is transferred to first node N1. Here, AND gate 415 may consist of a serially connected NAND gate 417 and inverter I5.

When reset control signal RST is low, a high is input to the gate of reset transistor RTR through third inverter I3 of reset controller 430 to turn ON the reset transistor RTR. Then, second node N2 is grounded to voltage level VSS and an output signal Q is reset to ground voltage level VSS through first and second inverters I1 and I2.

When reset control signal RST is high and clock signal CLK is low, third transfer gate TG3 of switch unit 410 is turned ON and fourth transfer gate TG4 is turned OFF such that data DI is applied to AND gate 415 via third transfer gate TG3. Since reset control signal RST is high, AND gate 415 transfers data DI to first node N1. Data DI is stored at first node N1 because fourth transfer gate TG4 and first transfer gate TG1 are turned OFF.

When clock signal CLK is low, second transfer gate TG2 of latch unit 420 maintains it's ON state. Then, second node N2, first and second inverters 11 and 12 and output node NOUT serve as a latch unit.

When reset control signal RST is high and clock signal CLK transitions to a high, fourth transfer gate TG4 of switch unit 410 and first transfer gate TG1 of latch unit 420 are turned ON. Data DI latched at first node N1 is transferred to second node N2 via first transfer gate TG1 and then made apparent at output node NOUT via first and second inverters I1 and I2 because second transfer gate TG2 is turned OFF.

Data DI of output node NOUT is output as output signal Q. Here, the output of first inverter I1 is an inverted output signal NQ. When clock signal CLK again transitions to low, new data DI is input to flip-flop 400 and the aforementioned operation is repeated.

In flip-flop 400 illustrated in FIG. 4, data DI passes through only two inverters I1 and I2 via second node N2 to be output when clock signal CLK transitions to high. Thus, the output delay time conventionally due to NAND gate 220 is reduced. That is, flip-flop 400 of FIG. 4 decreases output delay time caused by a circuit logic adapted to reset the flip-flop circuit.

While the circuit operation and configuration adapted to reset flip-flop 400 in response to reset control signal RST has been described in the embodiment shown in FIG. 4, the scope of the present invention is not limited to only this example of the reset operation, but may be otherwise implemented in a logic circuit similarly carrying out the reset operation.

Embodiments of the invention may be advantageously used, for example, in contemporary semiconductor devices operating at a high speed. In particular, embodiments of the invention may be within a read pass circuit adapted for use in a flash memory device requiring a high-speed operation.

Another embodiment of the invention may be explained in the context of flip-flop 400 illustrated in FIG. 4. Here, a first transfer means corresponds to third transfer gate TG3 of FIG. 4 and a first latch means corresponds to fourth transfer gate TG4 and AND gate 415 of FIG. 4. A second transfer means corresponds to first transfer gate TG1 of FIG. 4 and a second latch means corresponds to second transfer gate TG2 and inverters I1 and I2 of FIG. 4.

In addition, a reset control means corresponds to reset controller 430 of FIG. 4. Otherwise, the flip-flop according to another embodiment of the present invention has the same configuration as flip-flop 400 shown in FIG. 4 so a detailed explanation will be omitted.

As described above, the flip-flop according to the present invention reduces data output delay time. More particularly, it decreases data output delay time caused by a circuit logic added to implement a set/reset function.

While the present invention has been particularly shown and described with reference to exemplary embodiments thereof, it will be understood by those of ordinary skill in the art that various changes in form and details may be made therein without departing from the scope of the present invention as defined by the following claims.

What is claimed is:

1. A flip-flop circuit comprising:
a switch unit adapted to transfer data to a first node in response to a clock signal;
a latch unit adapted to latch data apparent at the first node at a second node and then output the data through an output node in response to the clock signal; and
a reset controller adapted to reset the output node in response to a reset control signal, the reset controller being connected between the second node and a first voltage and comprising a reset transistor having a gate adapted to receive an inverted reset control signal.

2. The flip-flop of claim 1, wherein the switch unit is further adapted to transfer data to the first node in response to a first level of the clock signal and output the data apparent at the first node in response to a second level of the clock signal.

3. The flip-flop of claim 1, wherein the latch unit is further adapted to latch the data apparent at the second node in response to the first level of the clock signal and output the data apparent at the second node through the output node in response to the second level of the clock signal.

4. The flip-flop of claim 1, wherein the latch unit comprises:
a first transfer gate adapted to transfer data apparent at the first node to the second node in response to the clock signal;
a second transfer gate switching data apparent at the second node to the output node in response to the clock signal; and
first and second inverters serially connected between the second node and the output node.

5. The flip-flop of claim 1, wherein the reset controller comprises:
a third inverter adapted to receive and invert the reset control signal; and
the reset transistor connected between the second node and the first voltage, the rest transistor having a gate adapted to receive the output of the third inverter.

6. The flip-flop of claim 1, wherein the switch unit comprises:
a fourth inverter adapted to receive and invert the clock signal;
a third transfer gate adapted to receive and store data in response to the clock signal and an output of the fourth inverter;
a fourth transfer gate switching data from the third transfer gate to the first node in response to the clock signal and the output of the fourth inverter; and
an AND gate logically ANDing the output of the third transfer gate and the reset control signal and adapted to transfer the ANDed result to the first node.

7. A flip-flop comprising:
a switch unit adapted to transfer data to a first node in response to a first level of a clock signal and a second level of a reset control signal;
a latch unit adapted to latch data apparent at the first node in response to a second level of the clock signal and the second level of the reset control signal; and
a reset controller adapted to reset the output node in response to a first level of the reset control signal,
wherein the data apparent at the second node is transferred via first and second serially connected inverters between the second node and the output node when the clock signal transitions to the second level.

8. The flip-flop of claim 7, wherein the latch unit comprises:
a first transfer gate adapted to transfer data apparent at the first node to the second node in response to the clock signal;
a second transfer gate switching data apparent at the second node to the output node in response to the clock signal; and
the first and second inverters serially connected between the second node and the output node.

9. The flip-flop of claim 7, wherein the reset controller comprises:
a third inverter adapted to receive and invert the reset control signal; and
an NMOS transistor connected between the second node and a first voltage, the NMOS transistor having a gate adapted to receive the output of the third inverter.

10. The flip-flop of claim 7, wherein the switch unit comprises:
a fourth inverter adapted to receive and invert the clock signal;
a third transfer gate adapted to receive and store data in response to the clock signal and the output of the fourth inverter;
a fourth transfer gate switching data from the third transfer gate to the first node in response to the clock signal and the output of the fourth inverter; and
an AND gate logically ANDing the output of the third transfer gate and the reset control signal and adapted to transfer the ANDed result to the first node.

11. The flip-flop of claim 7, wherein the first level is low and the second level is high.

12. A flip-flop circuit comprising:
first transfer means transferring data in response to a clock signal and an inverted clock signal;
first latch means storing the data output from the first transfer means at a first node in response to the clock signal and the inverted clock signal;
second transfer means transferring the data output from the first latch means in response to the clock signal and the inverted clock signal;
a second latch means storing the data output from the second transfer means at a second node and outputting it to an output node in response to the clock signal and the inverted clock signal; and
a reset control means resetting the output node in response to a reset control signal,
wherein data apparent at the first node is transferred via first and second inverters serially connected between the second node and the output node when the clock signal transitions to a second level.

13. The flip-flop of claim 12, wherein the first transfer means comprises a transfer gate transferring the data in response to a first level of the clock signal, and the second transfer means comprises a transfer gate switching data apparent at the first node to the second node in response to a second level of the clock signal.

14. The flip-flop of claim 12, wherein the first latch means comprises:
a transfer gate switching data apparent at the first transfer means to the first node in response to the second level of the clock signal; and
an AND gate ANDing the output of the first transfer means and the reset control signal and transferring the ANDed result to the first node.

15. The flip-flop of claim 12, wherein the second latch comprises:
a transfer gate switching data apparent at the second node to the output node in response to the first level of the clock signal; and
the first and second inverters serially connected between the second node and the output node.

16. The flip-flop of claim 12, wherein the reset control means comprises:
a third inverter inverting and outputting the reset control signal; and
an NMOS transistor connected between the second node and a first voltage, the NMOS transistor having a gate receiving the output of the third inverter.
